(19) United States
(12) Patent Application Publication
(10) Pub. No.: US 2026/0340220 A1
(43) Pub. Date: Oct. 29, 2026

(54) ROAD DETERIORATION MANAGEMENT SYSTEM AND ROAD DETERIORATION MANAGEMENT METHOD

(71) Applicant: TOYOTA JIDOSHA KABUSHIKI KAISHA, Aichi-ken (JP)

(72) Inventors: Kei KAWASAKI, Funabashi-shi (JP); Yuki ICHIOKA, Kawasaki-shi (JP); Yuta EZOE, Tokyo-to (JP); Masato SAKOU, Takarazuka-shi (JP); Nasif NAYEER, Tokyo-to (JP)

(21) Appl. No.: 19/651,793

(22) Filed: Apr. 20, 2026

(30) Foreign Application Priority Data
Apr. 25, 2025 (JP) 2025-072925

(51) Int. Cl. G06F 30/18

(52) U.S. Cl. CPC G06F 30/18

(57) ABSTRACT

The road deterioration management system disclosed herein comprises a simulator that performs simulation using a digital twin model simulating a management area, multiple IoT devices that acquire data related to road deterioration, a data server that collects and processes data acquired by the IoT devices, and a mobile flow control system that controls the flow of a mobile object within the management area. The simulator predicts the progression of road deterioration using the digital twin model based on data concerning road deterioration factors and road deterioration conditions acquired from the data server, adjusts the digital twin model based on the comparison result between the observed road deterioration condition data acquired from the data server and the predicted degree of road deterioration progression, and adjusts the parameters of the mobile flow control system based on the predicted degree of road deterioration progression.

### CROSS-REFERENCE TO RELATED APPLICATION

The present application claims priority under 35 U.S.C. § 119 to Japanese Patent Application No. 2025-072925, filed on Apr. 25, 2025, the contents of which application are incorporated herein by reference in their entirety.

### BACKGROUND

### Field

The present disclosure relates to a system and method for managing deterioration of a road maintained within a management area, particularly a system configured to perform management using IoT technology, and a method for performing management using IoT technology.

### Background Art

JP2020-086965A discloses a prior art related to managing road deterioration. However, as literature illustrating the technical level in the technical field relevant to the present disclosure, in addition to JP2020-086965A, JP2019-185443A and WO2023/042238A1 can be cited as examples.

According to the prior art disclosed in JP2020-086965A, the road life is predicted, and vehicle traffic is controlled to extend the road life. Controlling vehicle traffic includes, for example, total volume control, which regulates the number of vehicles passing, and weight control, which regulates the passage of vehicles exceeding a predetermined weight. In this prior art, to predict the road life, axle load meters are installed on the road to measure the weight of passing vehicles, and road damage is calculated based on the weight using a predetermined formula.

However, the vehicle weight is only one parameter affecting road deterioration, and predictions from the formula provide only a rough estimate. Furthermore, while the prior art could predict the overall deterioration of roads equipped with axle load meters, it could not predict deterioration for specific sections. Particularly on roads with frequent vehicle access, like general roads, there is a risk that only deterioration near the axle load meters could be predicted.

### SUMMARY

The present disclosure was made in view of the above issues. One objective of the present disclosure is to provide a road deterioration management system and a road deterioration management method capable of predicting road deterioration with high accuracy and managing it appropriately.

According to one embodiment of the present disclosure, the road deterioration management system is a system for managing deterioration of a road maintained within a management area, comprising a simulator, a plurality of IoT devices, a data server, and a mobile flow control system. The simulator is configured to perform simulation using a digital twin model simulating the management area. The plurality of IoT devices are configured to acquire data related to road deterioration from the management area. The data server is configured to collect and process the data acquired by the plurality of IoT devices. The mobile flow control system is configured to control the flow of a mobile object within the management area.

The simulator is configured to perform at least the following three processes. The first process is predicting degree of road deterioration progression using the digital twin model based on data concerning road deterioration factors and road deterioration conditions acquired from the data server. The second process is adjusting the digital twin model based on a result of comparing observed data of deterioration conditions acquired from the data server with predicted degree of road deterioration progression. The third process is performing parameter study to suppress progression of road deterioration by adjusting parameters of the mobile flow control system based on the predicted degree of road deterioration progression.

According to one embodiment of the present disclosure, the road deterioration management method is a method for managing deterioration of a road maintained within a management area, comprising at least the following five steps. The first step is acquiring data related to road deterioration from the management area using a plurality of IoT devices. The second step is collecting and processing the data acquired by the plurality of IoT devices from a data server. The third step is predicting degree of road deterioration progression using a digital twin model simulating the management area based on data concerning road deterioration factors and road deterioration conditions acquired from the data server. The fourth step is adjusting the digital twin model based on a result of comparing observed road deterioration condition data acquired from the data server with predicted degree of road deterioration progression. The fifth step is performing parameter study to suppress progression of road deterioration by adjusting parameters of a mobile flow control system configured to control a flow of a mobile object within the management area, based on the predicted degree of road deterioration progression.

According to one embodiment of the present disclosure, various data related to road deterioration can be collected from the management area by the plurality of IoT devices and sent to the data server. Then, by retrieving the data concerning road deterioration factors and road deterioration conditions from the data server and inputting it into the digital twin model, the degree of road deterioration progression can be predicted. The digital twin model is adjusted based on the comparison result between the observed road deterioration condition data and the predicted degree of road deterioration progression, ensuring that the predicted degree of road deterioration progression remains high accuracy. By performing the parameter study based on this highly accurate predicted degree of road deterioration progression, the parameters of the mobile flow control system can be appropriately adjusted to suppress progression of road deterioration.

### BRIEF DESCRIPTION OF DRAWINGS

FIG. 1 is a schematic diagram showing an overview of a road deterioration management system according to one embodiment of the present disclosure.

FIG. 2 is a diagram showing a specific example of the configuration of a management area managed by the road deterioration management system.

FIG. 3 is a diagram showing a specific example of the configuration of a data server provided by the road deterioration management system.

FIG. 4 is an illustration showing a specific example of the configuration of a digital twin simulator provided by the road deterioration management system.

FIG. 5 is a flowchart illustrating a method for determining countermeasures based on the predicted degree of road deterioration progression.

### DETAILED DESCRIPTION

### 1. Overview of Road Deterioration Management System

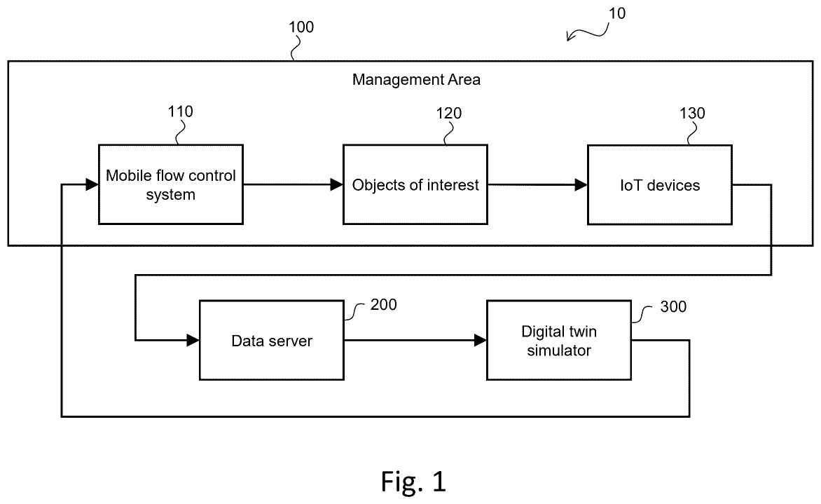

The road deterioration management system according to one embodiment of the present disclosure is a system that manages deterioration of a road maintained within a management area using IoT technology. The following describes the overview of the road deterioration management system using FIG. 1.

As shown in FIG. 1, the road deterioration management system 10 has a management area 100 defined. The management area 100 is an area containing roads subject to management by the road deterioration management system 10. Typically, the management area 100 is a closed-type city isolated from its surroundings by fences and gates, such as some smart cities or demonstration cities. However, a section without physical barriers separating it from surrounding areas, such as an administrative district, can also constitute the management area 100. Furthermore, the management area 100 includes road networks formed by numerous connected roads. Additionally, areas with only sidewalks, such as shopping malls or theme parks, can also constitute the management area 100.

The road deterioration management system 10 includes a mobile flow control system 110. The mobile flow control system 110 is installed within the management area 100 and is a system that controls the flow of mobile objects affecting road deterioration. When the management target of the road deterioration management system 10 is a roadway, the mobile objects whose flow is controlled by the mobile flow control system 110 refer to vehicles, namely automobiles such as passenger cars, buses, and trucks, as well as two-wheeled vehicles such as motorcycles and scooters. When the management target of the road deterioration management system 10 is a sidewalk, the moving objects whose flow is controlled by the moving object flow control system 110 refer to people and small mobility devices permitted to travel on the sidewalk.

The road deterioration management system 10 comprises a plurality of IoT devices 130. The IoT devices 130 are sensing devices deployed within the management area 100 and connected to the internet, used to acquire real-time data related to road deterioration. The IoT devices 130 may be fixed-location sensing devices or sensing devices with variable locations. Furthermore, the IoT devices 130 may be dedicated sensing devices for managing road deterioration or sensing devices also used for other purposes.

The management area 100 contains multiple objects of interest 120. Objects of interest 120 are either control targets of the mobile flow control system 110, or entities affected by the control of mobile flow by the mobile flow control system 110, and are also observation targets for the IoT devices 130. That is, the control results from the mobile flow control system 110 are physically reflected in objects of interest 120 and are converted into data through observation by the IoT devices 130. However, the objects observed by the IoT devices 130 also include items other than those controlled by the mobile flow control system 110 or affected by the control of the flow of mobile objects.

The road deterioration management system 10 includes a data server 200. The form of the data server 200 is not limited; it may be a single server or a collection of multiple servers. The IoT devices 130 are connected to the data server 200 via the Internet. The data server 200 is configured to collect and store various real-time data acquired by the IoT devices 130.

The road deterioration management system 10 includes a digital twin simulator 300. The digital twin simulator 300 is a device that performs simulation using a digital twin model simulating the management area 100. The data server 200 is connected to the input of the digital twin simulator 300, and the mobile flow control system 110 is connected to its output. The digital twin simulator 300 and the data server 200 may be connected via a network, may be provided within the same computer, or may share hardware. The digital twin simulator 300 is configured to acquire simulation data from the data server 200 and to provide control data generated based on the simulation to the mobile flow control system 110.

### 2. Specific Example of Management Area Configuration

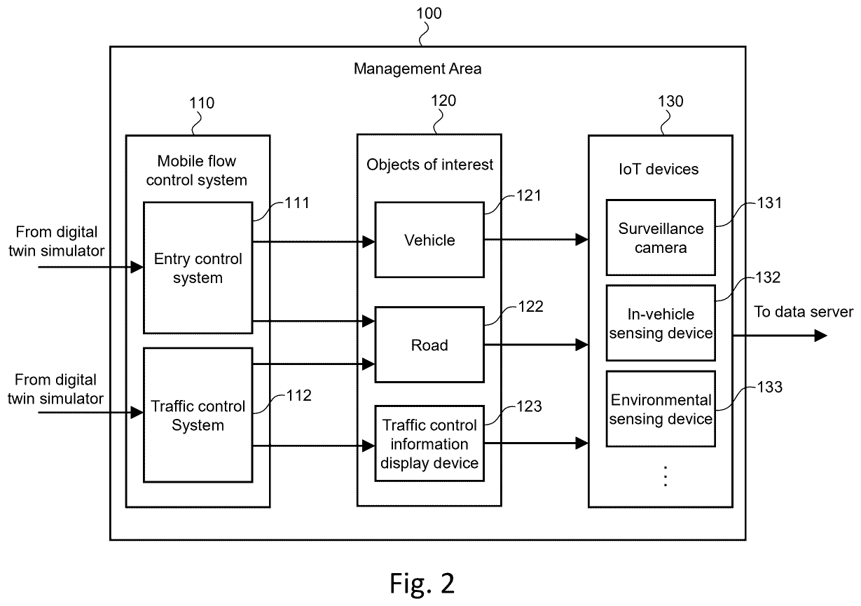

Next, a specific example of the configuration of the management area 100 is described using FIG. 2. In this specific example, the management area 100 is a closed-type city isolated from its surroundings by fences and gates.

The mobile flow control system 110 installed in the enclosed city management area 100 includes an entry control system 111. The entry control system 111 is a system that controls the entry of mobile objects into the management area 100, specifically the entry of vehicles 121 using the roads within the management area 100. The entry control system 111 is configured, for example, to switch between permitting and prohibiting vehicles entry into the management area 100 by controlling entry gates. Furthermore, the entry control system 111 is configured to control the number of vehicles 121 entering per unit time and the number of vehicles 121 entering per time period by controlling the opening and closing of entry gates. Parameters controlling the operation of the entry control system 111 are adjusted by control data input from the digital twin simulator 300. Note that if the management area 100 is an open area, such as a typical urban area, such an entry control system is not provided.

The mobile flow control system 110 includes a traffic control system 112 that controls traffic within the management area 100. The traffic control system 112 is a system that can also be installed in open areas such as general urban districts. The specific targets controlled by the traffic control system 112 are traffic control information display devices 123, such as traffic signals, road signs, and road markings. The traffic control system 112 is configured to alter the flow of vehicles 121 by switching the displays of the traffic control information display devices 123. For example, to suppress vehicle entry onto a deteriorating road 122, the displays of the traffic control information display devices 123 can be appropriately controlled to prohibit entry onto that road 122 during certain times or to divert traffic around it. Parameters controlling the operation of the traffic control system 112 are adjusted by control data input from the digital twin simulator 300.

Vehicles 121 entering the management area 100 are subject to entry control by the entry control system 111. Roads 122 within the management area 100 are subject to entry control by the entry control system 111 and also to control of vehicle flow by the traffic control system 112. Furthermore, the traffic control information display devices 123 are control targets of the traffic control system 112. In this specific example, vehicles 121, roads 122, and traffic control information display devices 123 are all objects of interest 120 and are observation targets of the IoT devices 130.

The IoT devices 130 includes surveillance cameras 131 installed at various locations within the management area 100. The surveillance cameras 131 are positioned to capture images of the road 122 and are used for fixed-point observation of the conditions of the road 122 and the types of vehicles 121 passing through (e.g., trucks, dump trucks, buses, passenger cars). Analysis of images captured by the surveillance camera 131 enables acquisition of real-world data related to deterioration of the road 122. Examples of such real-world data include information on road deterioration conditions, such as cracks or subsidence in the road surface caused by passing vehicles, as well as data on factors contributing to road deterioration, such as traffic volume of vehicles and pedestrians on the road and vehicle types.

The IoT devices 130 includes an in-vehicle sensing device 132 mounted on the vehicle 121. The in-vehicle sensing device 132 includes an acceleration sensor, a GPS sensor, a vehicle speed sensor, etc. Data regarding locations where deterioration, such as potholes, has occurred and the deterioration conditions of the road 122 can be acquired from shocks in the vertical direction of the vehicle 121 measured by the acceleration sensor. The GPS sensor and the vehicle speed sensor can provide data on traffic congestion, which is a factor contributing to road deterioration. Congestion tends to accelerate deterioration of the road 122. The in-vehicle sensing device 132 can acquire real-time data related to deterioration of the road 122 from various points along the road 122 traversed by vehicle 121.

The IoT devices 130 includes environmental sensing devices 133 installed at various locations within the management area 100. The environmental sensing devices 133 include sunlight sensors, rainfall sensors, temperature sensors, pH sensors, etc. From the environmental sensing devices 133, real-time data concerning environmental factors and weather conditions affecting deterioration of the road 122 can be acquired as data related to road deterioration factors.

In addition to the above sensing devices, the IoT devices 130 also includes weight sensors embedded in the road 122 and transmitters for vehicle identification information (information identifying the vehicle type). Furthermore, for example, when the road is a sidewalk, the IoT devices 130 also includes smartphones and smartwatches. Data regarding pedestrian flow within the management area 100 can be acquired via the GPS sensors built into these devices. Additionally, locations where people are prone to stumbling can be identified based on posture changes detected by acceleration sensors and gyroscope sensors.

### 3. Specific Example of Data Server Configuration

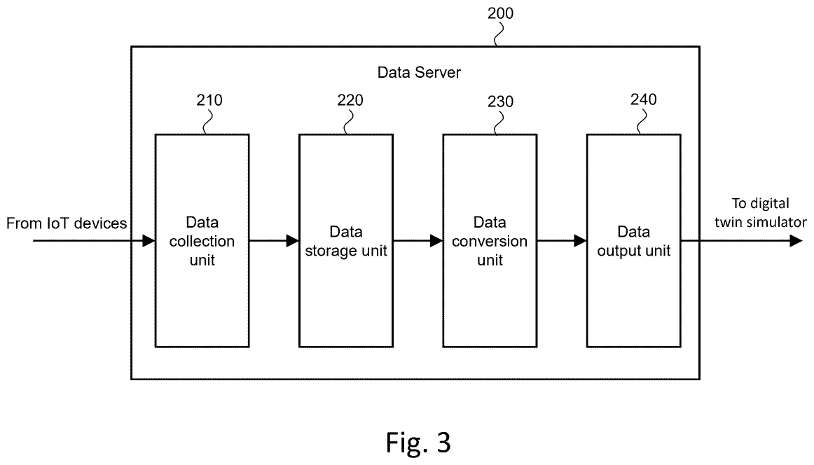

Next, a specific example of the configuration of the data server 200 is explained using FIG. 3. As shown in FIG. 3, the data server 200 comprises a data collection unit 210, a data storage unit 220, a data conversion unit 230, and a data output unit 240. These elements are realized through the cooperation of the processing circuitry and memory, which constitute the hardware of the data server 200, and the program stored in the memory and executed by the processing circuitry.

The data collection unit 210 is connected to the Internet and collects various real data acquired by the IoT devices 130. The data storage unit 220 stores the real data collected by the data collection unit 210 in the memory, categorized by data type. The format of the real data stored in the memory varies depending on the type of the IoT devices 130 that acquired the real data. The data conversion unit 230 converts the real data stored in the memory into a format processable by the digital twin simulator 300. The data output unit 240 outputs the converted real data, processed by the data conversion unit 230, to the digital twin simulator 300 in response to requests from the digital twin simulator 300.

### 4. Specific Example of Digital Twin Simulator Configuration

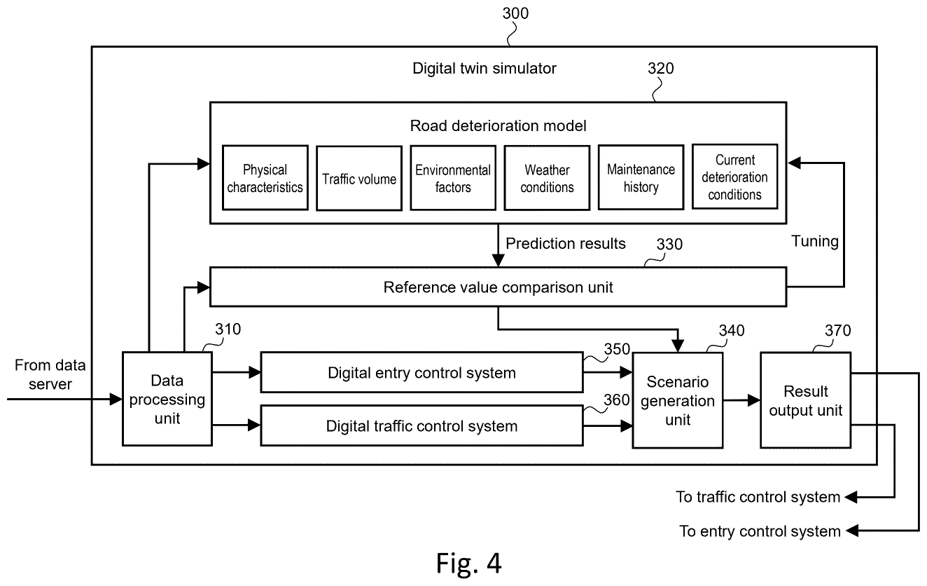

Next, a specific example of the configuration of the digital twin simulator 300 is explained using FIG. 4. As shown in FIG. 4, the digital twin simulator 300 comprises a data processing unit 310, a road deterioration model 320, a reference value comparison unit 330, a scenario generation unit 340, a digital entry control system 350, a digital traffic control system 360, and a result output unit 370. These elements are realized through the cooperation of the processing circuitry and memory, which constitute the hardware of the digital twin simulator 300, and the program stored in the memory and executed by the processing circuitry.

The data processing unit 310 acquires data required for simulation by the digital twin simulator 300 from the data server 200. The data processing unit 310 inputs, to the road deterioration model 320, the reference value comparison unit 330, the digital entry control system 350, and the digital traffic control system 360, data required by each of these components, respectively.

The road deterioration model 320 is a digital twin model simulating the management area 100, and is a machine learning model configured to predict the degree of deterioration progression of the road 122 within the management area 100. The road deterioration model 320 possesses parameters causally related to the degree of deterioration progression of the road 122, such as physical characteristics, traffic volume, environmental factors, weather conditions, maintenance history, and current deterioration conditions. Real data corresponding to each parameter acquired from the data server 200, namely real data regarding the deterioration factors and deterioration conditions of the road 122, is input to the road deterioration model 320. However, the real data used in the road deterioration model 320 need not necessarily be real-time or near-real-time data; historical data may also be used. When historical data is also used, weighting is applied according to the age of the data. The road deterioration model 320 predicts a degree of road deterioration progression for each pre-set section of the road 122. The road deterioration model 320 can also predict a degree of road deterioration progression for specific spots where deterioration, such as cracking or settlement, has been detected.

The reference value comparison unit 330 obtains the predicted degree of road deterioration progression from the road deterioration model 320 and acquires the observed deterioration condition data contained in the real data from the data processing unit 310. The reference value comparison unit 330 compares the predicted degree of road deterioration progression with the observed data and adjusts the road deterioration model 320, i.e., performs hyperparameter tuning, to reduce the discrepancy between the predicted degree of road deterioration progression and the observed data. The reference value comparison unit 330 repeatedly adjusts the road deterioration model 320 at a fixed cycle, thereby maintaining the road deterioration model 320 in a latest state that reflects current deterioration conditions of the road 122.

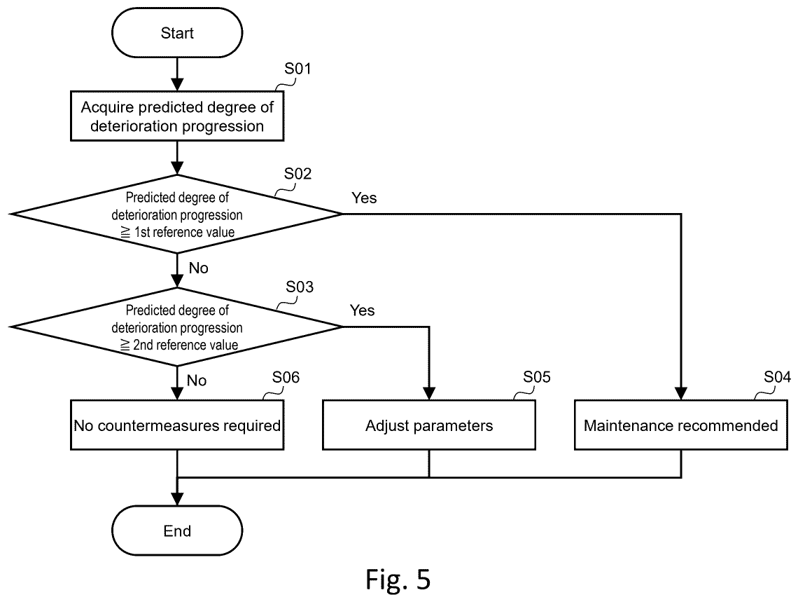

Furthermore, the reference value comparison unit 330 compares the predicted degree of road deterioration progression with a predetermined reference value and determines a countermeasure corresponding to the predicted degree of road deterioration progression. FIG. 5 is a flowchart showing the method for determining countermeasures corresponding to the predicted degree of road deterioration progression by the reference value comparison unit 330. The reference value comparison unit 330 determines countermeasures corresponding to the predicted degree of road deterioration progression according to this flowchart.

First, in step S01, the reference value comparison unit 330 acquires the predicted degree of road deterioration progression from the road deterioration model 320. Next, in step S02, the reference value comparison unit 330 determines whether the predicted degree of road deterioration progression is equal to or greater than a first reference value. If the predicted degree of road deterioration progression is equal to or greater than the first reference value, it is determined that suppressing progression of deterioration of the road 122 is difficult even by adjusting the parameters of the mobile flow control system 110. The reference value comparison unit 330 then executes step S04. In step S04, the reference value comparison unit 330 recommends maintenance of the road 122 to the administrator managing the management area 100.

If the predicted degree of road deterioration progression is lower than the first threshold value, the threshold comparison unit 330 executes step S03. In step S03, the threshold comparison unit 330 determines whether the predicted degree of road deterioration progression is equal to or greater than the second threshold value. The second threshold value is set to a value smaller than the first threshold value. If the predicted degree of road deterioration progression is equal to or greater than the second threshold value, the threshold comparison unit 330 executes step S05. In step S05, the reference value comparison unit 330 decides to adjust the parameters of the mobile flow control system 110.

If the predicted degree of road deterioration progression is lower than the second threshold value, the threshold comparison unit 330 executes step S06. In step S06, the threshold comparison unit 330 determines that no countermeasures against the deterioration of the road 122 are currently necessary. That is, the threshold comparison unit 330 selects waiting processing for the prediction result generated by the road deterioration model 320.

Referring back to FIG. 4, the configuration of the digital twin simulator 300 will be further described. When the reference value comparison unit 330 determines that the parameters of the mobile flow control system 110 should be adjusted, this determination is notified to the scenario generation unit 340. The scenario generation unit 340 is configured to perform parameter study to suppress progression of deterioration of the road 122 by adjusting the parameters of the mobile flow control system 110.

The scenario generation unit 340 performs the parameter study using the digital entry control system 350 and the digital traffic control system 360. These digitally simulate the real-world entry control system 111 and traffic control system 112, reflecting the latest real-world conditions through real-time data acquired from the data server 200. Parameters subject to the parameter study include, for example, entry gate opening times and frequencies, traffic signal indications (e.g., switching between red and green signals), and the displayed content of road signs and markings (e.g., permitted travel directions, speed limits, etc.). The scenario generation unit 340 calculates the optimal values for each parameter of the entry control system 111 and traffic control system 112 that are most effective in suppressing progression of deterioration of the road 122.

A specific example of a scenario generated by the scenario generation unit 340 is described below. In this specific example, the road 122 within the management area 100 includes multiple roads, such as Road A and Road B, and the deterioration states of both are being observed.

The first specific example is a case where both Road A and Road B are observed to have rapid deterioration rates. In this case, the scenario generation unit 340 generates a scenario, for example, that reduces overall traffic volume. In this scenario, the optimal values for each parameter are calculated, for example, to restrict entry into the management area 100 by controlling the entry gates.

The second specific example is a case where the deterioration rate is observed to be fast on Road A, while the deterioration rate is observed to be very slow on Road B. In this case, the scenario generation unit 340 generates a scenario, for example, that reduces traffic volume on Road A while increasing traffic volume on Road B, so as not to reduce overall traffic volume, i.e., so as not to impair the convenience of city residents. In this scenario, the optimal values for each parameter are calculated, for example, to change the permitted direction of travel by controlling the display of road signs.

The result output unit 370 outputs the optimal values for each parameter calculated by the scenario generation unit 340 as control data to the entry control system 111 and the traffic control system 112. Based on the control data input from the result output unit 370, the optimal values are set for the respective parameters of the entry control system 111 and the traffic control system 112.

The entry control system 111 controls the number of vehicles 121 entering the management area 100 according to the input control data. The traffic control system 112 controls traffic within the management area 100 according to the input control data. Consequently, the flow of vehicles 121 within the management area 100 is controlled to suppress progression of deterioration of the road 122.

### 5. Effects

According to the road deterioration management system 10 of this embodiment, various real-world data related to the deterioration of the road 122 can be collected by the IoT devices 130 existing within the management area 100. The collected real-world data is gathered and stored in the data server 200, then converted into a format processable by the digital twin simulator 300. Then, by extracting real data concerning the deterioration factors and deterioration conditions of the road 122 from the data server 200 and inputting it into the digital twin simulator 300, deterioration of the road 122 can be predicted. The road deterioration model 320 of the digital twin simulator 300 is adjusted based on the results of comparing the observed deterioration condition data with the predicted degree of road deterioration progression, so the accuracy of the predicted degree of road deterioration progression is always maintained at a high level. Based on this highly accurate predicted degree of road deterioration progression, performing a parameter study of the mobile flow control system 110 allows its parameters to be adjusted to optimal values, thereby suppressing progression of deterioration of the road 122.

What is claimed is:

1. A road deterioration management system for managing deterioration of a road maintained within a management area, comprising:
a simulator configured to perform simulation using a digital twin model simulating the management area;
a plurality of IoT devices configured to acquire data related to road deterioration from the management area;
a data server configured to collect and process the data acquired by the plurality of IoT devices; and
a mobile flow control system configured to control a flow of a mobile object within the management area,
wherein the simulator is configured to execute:
prediction of degree of road deterioration progression using the digital twin model based on data concerning road deterioration factors and road deterioration conditions acquired from the data server,
adjustment of the digital twin model based on a result of comparing observed road deterioration condition data acquired from the data server with predicted degree of road deterioration progression, and
parameter study to suppress progression of road deterioration by adjusting parameters of the mobile flow control system based on the predicted degree of road deterioration progression.

2. The road deterioration management system according to claim 1, wherein
the simulator is configured to:
perform the parameter study when the predicted degree of road deterioration progression is less than a first reference value, and
perform recommendation for maintenance of the road when the predicted degree of road deterioration progression is equal to or greater than the first reference value.

3. The road deterioration management system according to claim 2, wherein
the simulator is configured to:
perform the parameter study when the predicted degree of road deterioration progression is equal to or greater than a second reference value that is smaller than the first reference value, and
perform waiting processing when the predicted degree of road deterioration progression is lower than the second reference value.

4. The road deterioration management system according to claim 1, wherein the plurality of IoT devices include at least one of a surveillance camera that captures images of the road and a sensor mounted on the mobile object.

5. The road deterioration management system according to claim 1, wherein the mobile flow control system includes at least one of a traffic control system that controls traffic within the management area and an entry control system that controls entry of the mobile object into the management area.

6. A road deterioration management method for managing deterioration of a road maintained within a management area, comprising:
acquiring data related to deterioration of the road from the management area using a plurality of IoT devices;
collecting and processing the data acquired by the plurality of IoT devices by a data server;
predicting degree of road deterioration progression using a digital twin model simulating the management area based on data concerning road deterioration factors and road deterioration conditions acquired from the data server;
adjusting the digital twin model based on a result of comparing observed road deterioration condition data acquired from the data server with predicted degree of road deterioration progression; and
performing parameter study to suppress progression of road deterioration by adjusting parameters of a mobile flow control system configured to control a flow of a mobile object within the management area, based on the predicted degree of road deterioration progression.
